(19) United States
(12) Patent Application Publication
(10) Pub. No.: US 2026/0120755 A1
(43) Pub. Date: Apr. 30, 2026

(54) SEMICONDUCTOR DEVICE

(71) Applicant: Renesas Electronics Corporation, Tokyo (JP)

(72) Inventors: Yohei SAWADA, Tokyo (JP); Masao MORIMOTO, Tokyo (JP); Daiki KITAGATA, Tokyo (JP)

(21) Appl. No.: 19/263,738

(22) Filed: Jul. 9, 2025

Related U.S. Application Data
(60) Provisional application No. 63/689,222, filed on Aug. 30, 2024.
(60) Provisional application No. 63/689,957, filed on Sep. 3, 2024.

(30) Foreign Application Priority Data
Dec. 19, 2024 (JP) 2024-224255

(51) Int. Cl. G11C 11/412

(52) U.S. Cl. CPC G11C 11/412

(57) ABSTRACT

A latch circuit has a first invertor circuit and a second inverter circuit. The latch circuit further has a third pMOS transistor and a third nMOS transistor that are connected between the first invertor circuit and the second invertor circuit. A write port circuit is configurated by a transfer gate made of a fourth pMOS transistor and a fourth nMOS transistor, and transfers a write data to an inverted-side storage node. A read port circuit is configurated by a transfer gate made of a fifth pMOS transistor and a fifth nMOS transistor, and transfers read date from a non-inverted-side storage node.

### CROSS-REFERENCE TO RELATED APPLICATIONS

The present application claims priorities from U.S. Patent Application No. 63/689,222 filed on Aug. 30, 2024 and No. 63/689,957 filed on Sep. 3, 2024 and from Japanese Patent Application No. 2024-224255 filed on Dec. 19, 2024, the contents of which are hereby incorporated by reference to this application.

### BACKGROUND

The present invention relates to a semiconductor device, for example, a semiconductor device having a memory.

There are disclosed techniques listed below.
[Non-Patent Document 1] M. Sinangil, et al., “A 290 mV Ultra-Low Voltage One-Port SRAM Compiler Design Using a 12T Write Contention and Read Upset Free Bit-Cell in 7 nm FinFET Technology”, VLSI 2018
[Non-Patent Document 2] H. Fujiwara, et al., “A 5 nm 5.7 GHz @1.0V and 1.3 GHz @0.5V 4 kb Standard-Cell-Based Two-Port Register File with a 16T Bitcell with No Half-Selection Issue”, ISSCC 2021

Non-Patent Document 1 discloses a SRAM macro having a memory cell made of twelve transistors. The memory cell is configured by a writing port circuit, a latch circuit, and a reading port circuit. The writing port circuit is configured by a transfer gate made of two transistors. The latch circuit is configured by six transistors including two cross-linked CMOS invertor circuits. The reading port circuit is configured by a driver circuit made of four transistors.

Non-Patent Document 2 discloses a SRAM macro having a memory cell made of sixteen transistors. The memory cell is configured by a writing port circuit, a latch circuit, and a reading port circuit. The writing port circuit is configured by a driver circuit made of four transistors. The latch circuit is configured by eight transistors that include two cross-linked CMOS invertor circuits and also handle a bit light mask operation. The reading port circuit is configured by a driver circuit made of four transistors.

### SUMMARY

Recently, for example, a semiconductor device handling various Artificial Intelligence (AI) processings representing image recognition spreads. In such a semiconductor device, for example, it is preferable to temporarily store processing data at various places diffused in the device. Therefore, a memory having a high speed and somewhat small capacity is required. As such a memory, a flip-flop, a Static Random Access Memory (SRAM), or the like is known.

In the SRAM, for example in a case of a single port, the memory cell can be configured by six transistors. However, the SRAM requires a peripheral circuit including various circuits representing a decoder, a sense amplifier, a light assist circuit, a lead assist circuit, and the like. Therefore, in the SRAM, as capacity is smaller, an area per one bit becomes larger. That is, area efficiency decreases. Meanwhile, the flip-flop has only to having only the decoder as the peripheral circuit. However, the flip-flop is configured by, for example, two D-latches made of about twenty transistors. Therefore, the flip-flop is applied to only cases in which the area per one bit is large and the capacity is practically small enough.

Therefore, from the viewpoint of enhancing the area efficiency, the memory that is complementary between the SRAM and the flip-flop is required. As a specific example, a memory suitable to retain about 16 to 24 pieces of 128-bit data is required. As one of such a memory, D latch macro is exemplified. The D latch macro can be configured by a memory cell made of 16 transistors as disclosed in, for example, Non-Patent Document 2, in other words, by a latch cell. However, for example, when such a case as to arrange the multiple D latch macros each having small capacity in the semiconductor device is assumed, it is desirable to further save the area of the latch cell.

An embodiment mentioned below is made from the viewpoint of this, and other problems and novel features will be apparent from the present specification and the accompanying drawings.

A semiconductor device according to one embodiment includes a write port circuit, a latch circuit, a read port circuit, and first and second storage nodes storing complementary data. The latch circuit has a first pMOS transistor and a first nMOS transistor that configure a first invertor circuit inputting/outputting the second/first storage nodes. In addition, the latch circuit has a second pMOS transistor and a second nMOS transistor that configure a second invertor circuit inputting/outputting the first/second storage nodes. Further, the latch circuit has a third pMOS transistor and a third nMOS transistor that are connected between the first invertor circuit and a power supply voltage node. The write port circuit is configured by a transfer gate made of a fourth pMOS transistor and a fourth nMOS transistor, and transfers write data to the first storage node. The read port circuit is configured by a transfer gate made of a fifth pMOS transistor and a fifth nMOS transistor, and transfers read data from the second storage node.

According to the above embodiment, to save the area can be achieved in the semiconductor device having the small-capacity memory.

### BRIEF DESCRIPTION OF THE DRAWINGS

FIG. 1 is a schematic view showing a configuration example of a semiconductor device according to a first embodiment.

FIG. 2 is a schematic view showing a configuration example of a main part of a peripheral circuit in a memory shown by FIG. 1.

FIG. 3 is a circuit diagram of a configuration example of a latch cell of FIG. 1.

FIG. 4A is a timing chart showing one example of a writing operation by the latch cell shown by FIG. 3.

FIG. 4B is a schematic view for supplementarily explaining the operation shown by FIG. 4A.

FIG. 5A is a timing chart showing one example of a reading operation by the latch cell shown by FIG. 3.

FIG. 5B is a schematic view for supplementarily explaining the operation shown by FIG. 5A.

FIG. 6A is a timing chart showing one example of a bit light mask operation by the latch cell shown by FIG. 3.

FIG. 6B is a schematic view for supplementarily explaining the operation shown by FIG. 6A.

FIG. 7A is a schematic view showing one example of design specifications of the latch cell shown by FIG. 3.

FIG. 7B is a schematic view showing one example of further design specifications of the latch cell shown by FIG. 3.

FIG. 8 is a view showing one example of the detailed design specification of the latch cell of FIG. 3, FIG. 7A, and FIG. 7B in a semiconductor device according to a second embodiment.

FIG. 9 is a perspective view showing a structure example of each MOS transistor configuring the latch cell in the semiconductor device according to the second embodiment.

FIG. 10 is a schematic view showing a layout configuration example of the latch cell shown by FIG. 3 and FIG. 8.

FIG. 11 is a schematic view showing a layout configuration example different from that of FIG. 10 of the latch cell shown by FIG. 3 and FIG. 8.

FIG. 12 is a view showing one example a detailed design specifications of the latch cell shown by FIG. 3, FIG. 7A, and FIG. 7B in a semiconductor device according to a third embodiment.

FIG. 13 is a schematic view showing a layout configuration example of the latch cell shown by FIG. 3 and FIG. 12.

FIG. 14 is a schematic view showing a layout configuration example different from a case of FIG. 13 in the latch cell shown by FIG. 3 and FIG. 12.

FIG. 15 is a perspective view showing a configuration example of each MOS transistor configurating a latch cell in a semiconductor device according a fourth embodiment.

FIG. 16 is a schematic view showing a layout configuration example of the latch cell shown by FIG. 3 and FIG. 12 in the semiconductor device according to the fourth embodiment.

FIG. 17 is a schematic view showing a layout configuration example different from a case of FIG. 16 of the latch cell shown by FIG. 3 and FIG. 12.

FIG. 18 is a circuit diagram showing a configuration example of a latch cell to be a comparative example.

FIG. 19 is a schematic view showing a layout configuration example of the latch cell shown by FIG. 18.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

In the following embodiments, a MOS Field Effect Transistor (MOSFET) is abbreviated as “MOS transistor”. A p-channel type MOSFET is abbreviated as “pMOS transistor”, and an n-channel type MOSFET is abbreviated as “nMOS transistor”. In the embodiments, by using the MOS transistor using an oxide film as a gate insulation film, explanation will be made for simple explanation. However, the gate insulation film is not necessarily limited to the oxide film.

Hereinafter, embodiments of the present invention will be explained based on the drawings. Note that in all the figures for explaining the embodiment, the same reference numerals are denoted by the same member in principle, and a repetitive description will be omitted.

### First Embodiment

### Outline of Semiconductor Device

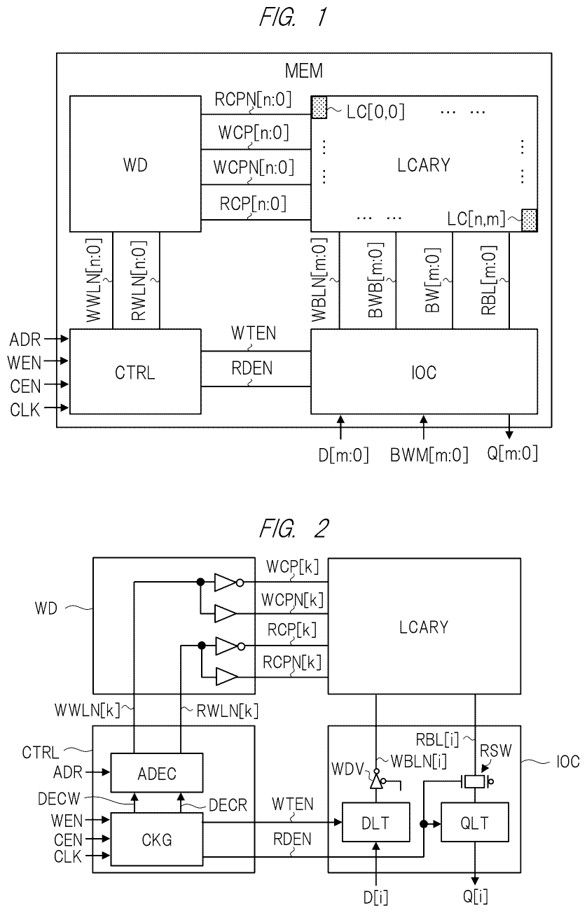

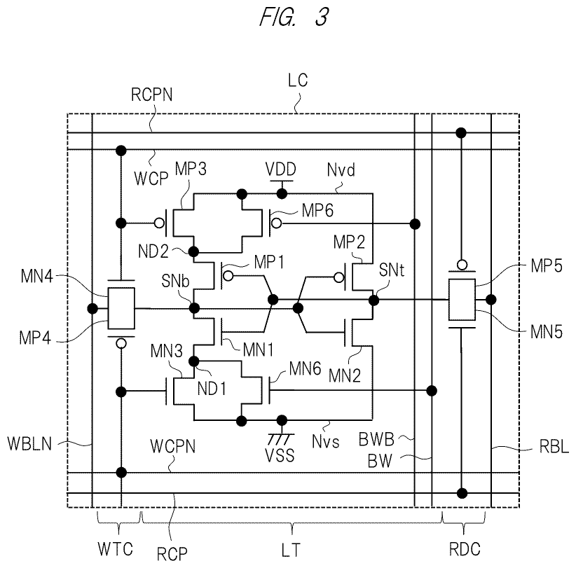

FIG. 1 is a schematic view showing a configuration example of a semiconductor device according to a first embodiment. FIG. 2 is a schematic view showing a configuration example of a main part of a peripheral circuit in a memory MEM shown by FIG. 1. The semiconductor device according to the first embodiment has at least a memory MEM shown by FIG. 3. The memory MEM is, for example, a D latch macro configured by a hard macro. The semiconductor device includes, for example, various logic circuits handling various AI processings. In this case, the semiconductor device can disperse and mount the memory MEM as shown by FIG. 1 into and on each location in the device in order to temporarily store processing data of the various logic circuits.

The memory MEM shown by FIG. 1 has a latch cell array LCARY, a memory control circuit CTRL, a word driver circuit WD, and a data input/output circuit IOC. The memory control circuit CTRL, the word driver circuit WD, and the data input/output circuit IOC is a peripheral circuit of the latch cell array LCARY. The latch cell array LCARY has “N (=n+1)×M (=m+1)” latch cells LC[0,0] to LC[n,m]. In this specification, the plurality of latch cells LC[0,0] to LC[n,m] are generically called a latch cell LC.

The memory control circuit CTRL controls the entire memory MEM. The memory control circuit CTRL mainly has a clock generation circuit CKG, and an address decoder ADEC as shown by FIG. 2. The clock generation circuit CKG inputs, for example, a clock signal CLK, a chip enable signal CEN, a write enable signal WEN, and the like from outside the memory MEM. The clock generation circuit CKG outputs, based on its input signal, a write decode instruction signal DECW or a read decode instruction signal DECR to an address decoder ADEC. In addition, the clock generation circuit CKG outputs, based on its input signal, a write enable signal WTEN or a read enable signal RDEN to the data input/output circuit IOC.

The address decoder ADEC inputs the address signal ADR from outside the memory MEM. The address decoder ADEC activates one write word line WWLN[k] based on the address signal ADR according to the write decode instruction signal DECW. The write word line WWLN[k] is one among the N write word line lines WWLN[n:0] shown by FIG. 1. Similarly, the address decoder ADEC activates one read word line RWLN[k] based on the address signal ADR according to the read decode instruction signal DECR. The read word line RWLN[k] is one among the N read word lines RWLN[n:0] shown by FIG. 1.

The word driver circuit WD drives “2×N” read selection line RCP[n:0], RCPN[n:0] to be complementary signal lines as shown by FIG. 1. The N read selection lines RCP[n:0] are non-inverted-side signal lines. In this specification, the N read selection lines RCP[n:0] are called non-inverted-side read selection signal lines RCP or simply called read selection signal lines RCP. Meanwhile, the remaining N read selection lines RCP[n:0] are inverted-side signal lines. In this specification, the N read selection lines RCP[n:0] are called inverted-side read signal lines RCPN or simply called read selection lines RCPN.

In addition, the word driver circuit WD drives “2×N” write selection lines WCP[n:0], WCPN[n:0] to be complementary signal lines. The N write selection lines WCP[n:0] are non-inverted-side signal lines. In this specification, the N write selection lines WCP[n:0] are generically called non-inverted-side write selection line WCP or simply called write selection lines WCP. Meanwhile, the remaining N write selection lines WCPN[n:0] are inverted-side signal lines. In this specification, the N write selection lines WCPN[n:0] are called inverted-side write selection lines WCPN or simply called write selection lines WCPN.

As shown in FIG. 2, the word driver circuit WD inputs each read word line RWLN[k], and drives each inverted-side read selection lines RCPN[k]. In addition, the word driver circuit WD inverts the signal of each read word line RWLN[k], thereby driving each non-inverted-side read selection line RCP[k]. Similarly, the word driver circuit WD inputs the signal of each write word line WWLN[k], and drives each inverted-side write selection line WCPN[k]. In addition, the word driver circuit WD inverts the signal of each write word line WWLN[k], thereby driving each non-inverted-side write selection line WCP[k].

The data input/output circuit IOC controls an input/output of data in and out the memory MEM. Specifically, the data input/output circuit IOC mainly has, as a write circuit, a write latch circuit DLT and a write driver WDV. In addition, the data input/output circuit IOC mainly has, as a read circuit, a read switch RSW and a read latch circuit QLT.

Firstly, during a writing operation, the data input/output circuit IOC inputs M-bit input data D[m:0] from outside the memory MEM as shown by FIG. 1. The write latch circuit DLT latches, as write data, the M-bit input data D[m:0] according to the write enable signal WTEN. The write driver WD transfers the latched M-bit write data to a latch cell array LCARY via the M inverted-side write bit lines WBLN[m:0].

The M-bit write data transferred from the write driver WDV is written into the M latch cells LC connected to the activated write selection line WCP. In this specification, the M inverted-side write bit lines WBLN[m:0] are called inverted-side write bit lines WBLN or simply called write bit lines WBLN.

Meanwhile, during a reading operation, the data input/output circuit IOC inputs the read data from the M latch cells LC via the M non-inverted-side read bit lines RBL[m:0]. The M latch cells LC are cells connected to the activated read selection line RCP. In this specification, the M non-inverted-side read bit lines RBL[m:0] are called non-inverted-side read bit lines RBL or simply called read bit lines RBL.

The read latch circuit QLT inputs read data from the M latch cells LC via the switch RSW according to the read enable signal RDN, and latches the inputted read data. That is, the read latch circuit QLT is different from the normal SRAM, inputs the read data without passing through the sense amplifier, and latches the inputted read data. Then, the read latch circuit QLT outputs, as output data Q[m:0], the latched M-bit read data to its outside.

In addition, the data input/output circuit IOC inputs M-bit bit write mask signal BWM[m:0] from outside the memory MEM as shown by FIG. 1. the bit write mask signal BWM[m:0] is used for masking some bits out of the M-bit input data D[m:0] during the writing operation. Consequently, for example, read modify write can be made unnecessary.

During a bit write mask operation, the write driver WDV shown by FIG. 2 outputs high impedance to the write bit line WBLN[k] of the bit to be masked. Consequently, the latch cell CL connected to the write bit line WBN[k] can maintain the now stored data regardless of the writing operation.

In addition, during the bit write mask operation, the data input/output IOC drives the M inverted-side bit write mask selection lines BWB[m:0] and the M non-inverted-side bit write mask selection lines BW[m:0]. Although their details are described later, the latch cell LC can more reliably maintain the now stored data by the drive of the selection line. In this specification, the M inverted-side bit write mask selection lines BWB[m:0] is called inverted-side bit write mask selection lines BWB or simply called bit write mask selection lines BWB. Similarly, the M non-inverted-side bit write mask selection lines BW[m:0] are called non-inverted-side bit write mask selection lines BW or simply called bit write mask selection lines BW.

Here, as shown in FIG. 1, a value of M (=m+1) representing a bit width is, for example, 128, 256, 1024, or the like. In addition, a value of N (=n+1) representing the number of word lines is, for example, 16, 32, 64, or the like. Generally, within a range of such memory capacity, the D latch macro can be advantage in comparison with the flip-flop and the SRAM from the viewpoint of the area efficiency. The D latch macro is also known as a macro in which an area ratio of a data storage region and a peripheral circuit region is in the middle of the flip-flop and the SRAM.

For example, the SRAM can include the sense amplifier, various assist circuits, and the like that are equal to a number according to a bit width. Therefore, as the bit width increases, the area ratio of the data input/output circuit IOC rises. Meanwhile, in the D latch macro, the sense amplifier, the various assist circuits, and the like are unnecessary. Therefore, the area ratio of the data input/output circuit IOC does not increase significantly as the bit width increases. As a result, in the D latch macro, even if the bit width increases, the area ratio can be enhanced.

Note that in FIG. 1, a case in which the memory MEM is a single port memory has been exemplified. However, the memory MEM may be a dual port memory that performs the reading operation and the writing operation independently. In this case, the memory MEM inputs a read address signal and a write address signal from outside. With this, a read selection line RCP and a write selection line WCP can be activated simultaneously.

### Configuration of Latch Cell (Embodiment)

FIG. 3 is a circuit diagram showing a configuration example of the latch cell LC of FIG. 1. The latch cell LC shown by FIG. 3 has a write port circuit WTC and a read port circuit RDC. The latch cell LC also has an inverted-side storage node (first storage node) SNb and a non-inverted-side storage node (second storage node) SNt that store complementary data.

A latch circuit LLT has 4 nMOS transistors MN1 to MN3 and MN6, 4 pMOS transistors MP1 to MP3 and MP6. The pMOS transistor (first pMOS transistor) MP1 and the nMOS transistor (first nMOS transistor) MN1 configure a first inverter circuit. The first inverter circuit performs a signal inverting operation by using the non-inverted-side storage node SNt/inverted-side storage node SNb as an input/output.

The pMOS transistor (second pMOS transistor) MP2 and the nMOS transistor (second nMOS transistor) MN2 configure a second inverter circuit. The second inverter circuit performs a signal inverting operation by using the inverted-side storage node SNb/non-inverted-side storage node SNt as an input/output.

The pMOS transistor (third pMOS transistor) MP3 is connected between the first invert circuit and a high-potential-side power supply voltage node Nvd. The nMOS transistor (third nMOS transistor) MN3 is connected between the first invert circuit and a low-potential-side power supply voltage node Nvs. A high-potential-side power supply voltage VDD is supplied to the high-potential-side power supply voltage node Nvd. A low-potential-side power supply voltage VSS is supplied to the low-potential-side power supply voltage node Nvs.

In addition, the pMOS transistor (sixth pMOS transistor) MP6 is connected to the pMOS transistor MP3 in parallel. The nMOS transistor (sixth nMOS transistor) MN6 is connected to the nMOS transistor MN3 in parallel. Although their details are described later, the pMOS transistor MP6 and the nMOS transistor MN6 are provided to realize a bit write mask function. Accordingly, the pMOS transistor MP6 and the nMOS transistor MN6 can be omitted when the bit write mask function is unnecessary.

The write port circuit WTC is configured by the pMOS transistor (fourth pMOS transistor) MP4 and the nMOS transistor (fourth nMOS transistor) MN4. The pMOS transistor MP4 and the nMOS transistor MN4 configure a transfer gate, and transfer write date to the inverted-side storage node SNb. Meanwhile, the read port circuit RDC is configured by a pMOS transistor (fifth pMOS transistor) MP5 and an nMOS transistor (fifth nMOS transistor) MN5. The pMOS transistor MP4 and the nMOS transistor MN4 configure a transfer gate, and transfer read data from the non-inverted-side storage node SNt.

Here, the latch cell CL shown by FIG. 3 is connected to the 8 signal lines (WCP, WCPN, RCP, RCPN, BW, BWB, WBLN, and RBL) as described in FIG. 1 and FIG. 2 in more detail. The non-inverted-side write selection line WCP and the inverted-side write selection line WCPN are activated when the writing operation is performed. The non-inverted-side read selection line RCP and the inverted-side read selection line RCPN are activated when the reading operation is performed. The read bit line WBLN transfers the write data to the latch cell LC.

The non-inverted-side bit write mask selection line BW and the inverted-side bit write mask selection line BWB are activated when a bit write mask operation is performed. That is, those bit write mask signal lines are activated when a high-impedance writing operation is performed to any of the plurality of latch cells LC. In other words, those signal lines is activated to maintain the data stored in any of the plurality of latch cells regardless of the writing operation.

The nMOS transistor (first nMOS transistor) MN1 is connected to the inverted-side storge node SNb and an intermediate node (first intermediate node) ND1. A gate of the nMOS transistor MN1 is connected to the non-inverted-side storage node SNt. The nMOS transistor (second nMOS transistor) MN2 is connected between the non-inverted-side storge node SNt and the low-potential-side power supply voltage node Nvs. A gate of the nMOS transistor MN2 is connected to the inverted-side storage node SNb.

An nMOS transistor (third nMOS transistor) MN3 is connected between the intermediate node ND1 and the low-potential-side power supply voltage node Nvs. A gate of the nMOS transistor MN3 is connected to the inverted-side write selection line WCPN. A nMOS transistor (fourth nMOS transistor) MN4 is connected between the write bit line WBLN and the inverted-side write selection line WCP.

An nMOS transistor (fifth nMOS transistor) MN5 is connected between the read bit line RBL and the non-inverted-side storage node SNt. A gate of the nMOS transistor MN5 is connected to the non-inverted-side read selection line RCP. The nMOS transistor (sixth nMOS transistor) MN6 is connected between the intermediate node ND1 and the low-potential-side power supply voltage node Nvs. A gate of the nMOS transistor MN6 is connected to the non-inverted-side bit write mask selection line BW.

The nMOS transistor (fifth nMOS transistor) MN5 is connected between the read bit line RBL and the non-inverted-side storage node SNt. A gate of the nMOS transistor MN5 is connected to the non-inverted-side read selection line RCP. The nMOS transistor (sixth nMOS transistor) MN6 is connected between the intermediate node ND1 and the low-potential-side power supply voltage node Nvs. A gate of the nMOS transistor MN6 is connected to the non-inverted-side bit write mask selection line BM.

The pMOS transistor (first pMOS transistor) MP1 is connected between the inverted-side storage node SNb and an intermediate node (second intermediate node) ND2. A gate of the pMOS transistor MP1 is connected to the non-inverted-side storage node SNt. A pMOS transistor (second pMOS transistor) MP2 is connected between the non-inverted-side storage node SNt and the high-potential-side power supply voltage node Nvd. A gate of the pMOS transistor MP2 is connected to the inverted-side write selection line WCPN.

A pMOS transistor (fifth pMOS transistor) MP5 is connected between the read bit line RBL and the non-inverted-side storage node SNt. A gate of the pMOS transistor MP5 is connected to the inverted-side read selection line RCPN. A pMOS transistor (sixth pMOS transistor) MP6 is connected between the intermediate node ND2 and the high-potential-side power supply voltage node Nnd. A gate of the pMOS transistor MP6 is connected to the inverted-side bit write mask selection line BWB.

### Operation of Latch Cell (Embodiment)

### Writing Operation

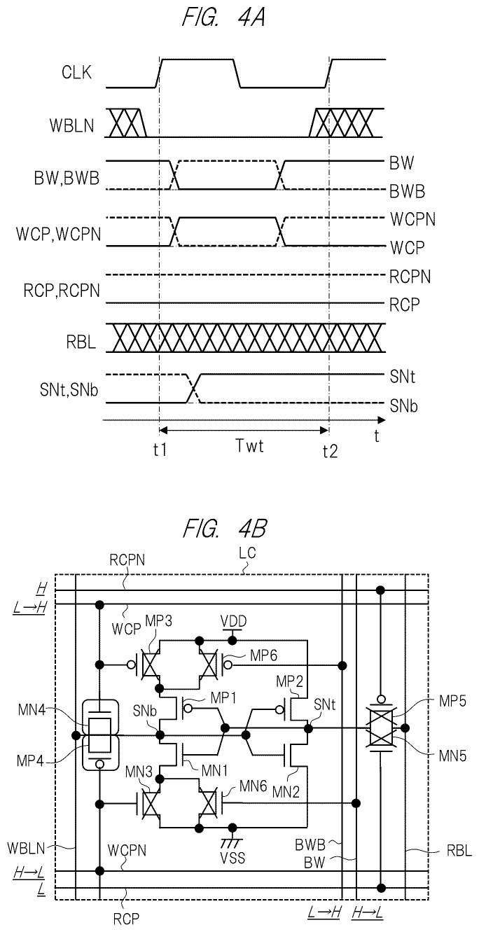

FIG. 4A is a timing chart showing one example of a writing operation by the latch cell LC shown by FIG. 3. FIG. 4B is a schematic view for supplementarily explaining the operation shown by FIG. 4A. FIG. 4B shows a state of each signal line in the latch cell LC and an on/off state of each transistor in a write period. In FIG. 4A, a period from time t1 to time t2, which is 1 cycle of a clock signal CLK, is a write period Twt. In the write period Twt, a read selection line RCP is in a deactivation state, here, is at an “L” level. Therefore, the pMOS transistor MP5 and the nMOS transistor MN5 are in the off state.

Meanwhile, the write selection line WCP transitions from the deactivation state to an activation state, here, from the “L” level to a “H” level. With this, the pMOS transistor MP4 and the nMOS transistor MN4 switch from the off state to the on state. In addition, the pMOS transistor MP3 and the nMOS transistor MN3 switch from the on state to the off state. Note that, here, since the bit write mask operation is not performed, the bit write mask selection line BW transitions from the activation state to the deactivation state, here, from the “H” level to the “L” level. With this, the pMOS transistor MP6 and the nMOS transistor MN6 switch from the on state to the off state.

In those states, for example, a case of rewriting the inverted-side storge node SNb from the “H” level to the “L” level is assumed. The write bit line, specifically, the inverted-side write bit line WBLN is at the “L” level at time t1. The pMOS transistor MP4 and the nMOS transistor MN4 that are in the on levels transfer the “L” level to the “H”-level storage node SNb.

At this time, the write bit line WBLN is driven by the write driver WDV shown by FIG. 2. Meanwhile, supply of the power supply voltage VDD to the pMOS transistor MP1 is blocked. Therefore, the inverted-side storage node SNb can be rewritten to the “L” level. Further, the pMOS transistor MP2 inputs the “L” level, thereby being capable of rewriting the non-inverted-side storage node SNt from the “L” level to the “H” level.

Then, the write selection line WCP transitions from the activation state to the deactivation state. The bit write mask selection line BW transitions from the deactivation state to the activation state. With this, the pMOS transistor MP4 and the nMOS transistor MN4 switch from the on state to the off state. The 2 pMOS transistors MP3, MP6 and the 2 nMOS transistors MN3, MN6 switch from the on state to the off state. Consequently, the writing operation is completed.

### Reading Operation

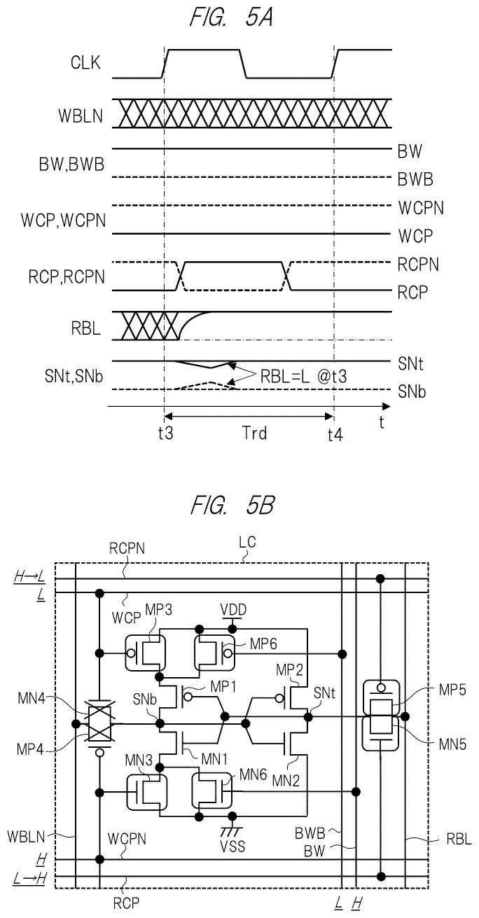

FIG. 5A is a timing chart showing one example of a reading operation by the latch cell LC shown by FIG. 3. FIG. 5B is a schematic view for supplementarily explaining the operation shown by FIG. 5A. FIG. 5B shows the state of each signal line in the latch cell LC and the on/off state of each transistor. In FIG. 5A, a period from time t3 to time t4, which is 1 cycle of the clock signal CLK, is a read period Trd.

In the read period Trd, the write selection line WCP is in the deactivation state, here, in the “L” level. Therefore, the pMOS transistor MP4 and the nMOS transistor MN4 are in the off state. The pMOS transistor MP3 and the nMOS transistor MN3 is in the on state. In addition, the bit write mask selection line BW is in the activation state, here, at the “H” level. Therefore, the pMOS transistor MP6 and the nMOS transistor MN6 are in the on state. Meanwhile, the read selection line RCP transitions from the deactivation state to the activation state, here, from the “L” level to the “H” level. With this, the pMOS transistor MP5 and the nMOS transistor MN5 switch from the off state to the on state.

In those states, for example, a case of reading out the non-inverted-side storage node SNt storing the “H” level is assumed. A voltage level of the read bit line RBL is variable at time t3. The pMOS transistor MP5 and the nMOS transistor MN5 that are in the on state connect the non-inverted-side storage node SNt to the read bit line RWL having a variable voltage level. At this time, when the read bit line RBL is at the “L” level, a voltage level of the non-inverted-side storage node SNt can be decreased from the “H” level. According to this, the voltage level of the inverted-side storage node SNb can also be increased from the “L” level.

Although detailed later, the voltage level of the rea bit line RBL can be correctly determined in the embodiment even if the voltage level of each storage node can be changed like this. As a result, the voltage level of the read bit line RBL becomes the “H” level. Then, the read selection line RCP transitions from the activation state to the deactivation state. With this, the pMOS transistor MP5 and the nMOS transistor MN5 switch from the on state to the off state. Consequently, the reading operation is completed.

### Bit Write Mask Operation

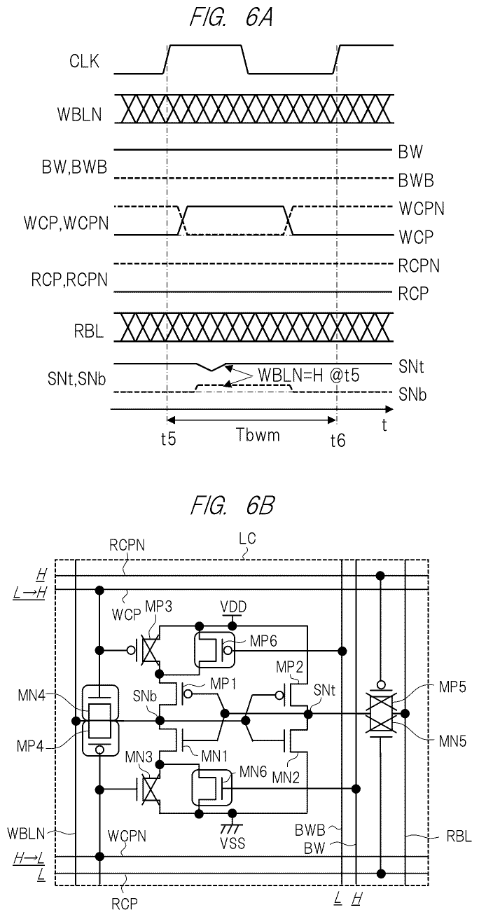

FIG. 6A is a timing chart showing one example of a bit light mask operation by the latch cell LC shown by FIG. 3. FIG. 6B is a schematic view for supplementarily explaining the operation shown by FIG. 6A. FIG. 6B shows the state of each signal line in the latch cell LC and the on/off state of each transistor in a bit write mask period. In FIG. 6A, a period from time t5 to time t6, which is 1 cycle of the clock signal CLK, is a bit write mask period Tbwm.

The bit write mask period Tbwm is different from the write period Twt shown by FIG. 4A in a state of the bit write mask selection line BW. That is, in the bit write mask period Tbwm, the bit write mask selection line BW is in the activation state, here, at the “H” level. With this, the pMOS transistor MP6 and the nMOS transistor MN6 are in the on state. As a result, the inverted-side storage node SNb is different from a case of FIG. 4, and is driven by the high-potential-side power supply voltage VDD or the low-potential-side power supply voltage DSS.

In such a state, for example, a case in which the inverted-side storage node SNb stores the “L” level is assumed. As described in FIG. 1 and FIG. 2, the write bit line WBLN is the high impedance in the bit write mask period Tbwm. That is, the voltage level of the write bit line WBLN is variable. The pMOS transistor MP4 and the nMOS transistor MN4 that are in the on state connect the write bit line WBLN, which has the variable voltage level, to the inverted-side storage node SNb.

At this time, when the write bit line WBLN is at the “H” level, the voltage level of the inverted-side storage node SNb can be increased from the “L” elver. According to this, the voltage level of the non-inverted-side storage node SNt can also be decreased from the “H” level. Although detailed later, the voltage level of each storage node can be correctly maintained in the embodiment even if the voltage level of each storage node can be changed like this. As a result, the inverted-side storage node SNb can maintain the “L” level, as it is, regardless of the writing operation.

About Difference with Latch Cell (Comparative Example)

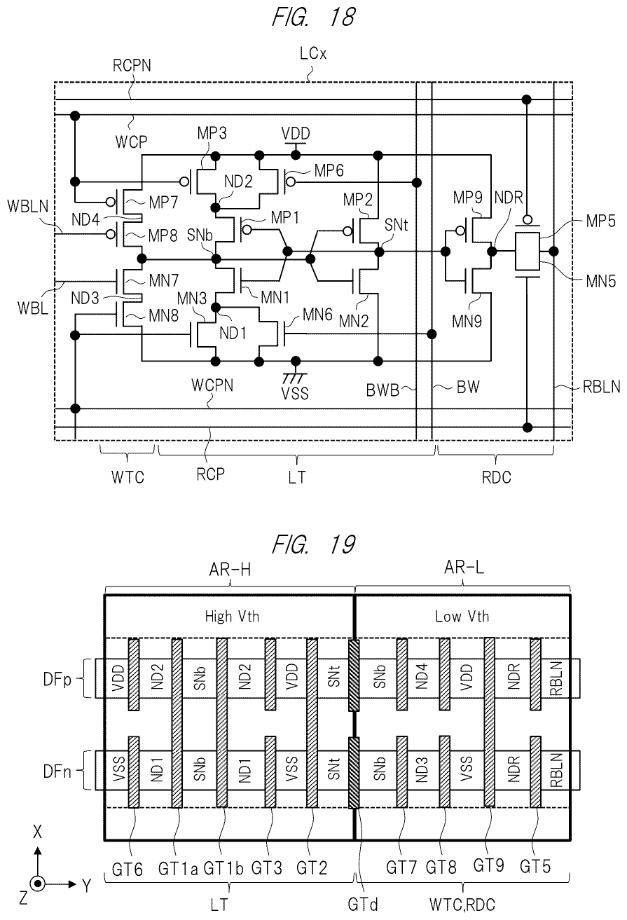

FIG. 18 is a circuit diagram showing a configuration example of a latch cell LCx to be a comparative example. The latch cell LCx to be the comparative example is different from the configuration example shown by FIG. 3 in configurations of the write port circuit WTC and the read port circuit RDC. The write port circuit WTC of FIG. 18 is configured by a driver circuit made of 2 pMOS transistors MP7, MP8 and 2 nMOS transistors MN7, MN8. In addition, the read port circuit WTC is configured by a driver circuit, which is made of a pMOS transistor MP9 and an nMOS transistor MN9, and a transfer gate. The transfer gate is configured by the pMOS transistor MP5 and the nMOS transistor MN5 similarly to the case of FIG. 3.

By this way, the latch cell LCx to be the comparative example is configured by a total of 16 transistors. Meanwhile, the latch cell LC shown by FIG. 3 is configured by a total of 12 transistors, or a total of 10 transistors if the bit write mask function is unnecessary. As a result, in the semiconductor device having the small-capacity memory, the area saving can be achieved. Specifically, the area saving of the semiconductor device can be achieved by itself using the D latch macro. In addition to this, by reducing the number of transistors in the latch cell LC, the area saving of the D latch macro itself can be achieved, and the further area saving of the semiconductor device can be achieved. Particularly, even when the D latch macro is dispersed at each position in the semiconductor device, the increase in the area can be suppressed.

However, as shown in FIG. 3, if each of the write port circuit WTC and the read port circuit RDC is configured only by the transfer gate, stability of the latch cell LC may decrease. That is, by the latch cell LC being connected to the write bit line WBLN and the read bit line RBL only via the transfer gate, the latch circuit LC may not be capable of storing the correct data. In the configuration example shown by FIG. 18, by the driver circuit being provided, such a concern does not arise.

As a case of being not capable of storing the correct data, for example, the following 3 cases are considered. As a first case, the data destruction at the time of the reading operation as shown by FIG. 5A and FIG. 5B is exemplified. That is, by the data of the “H”/“L” level previously retained in the read bit line RBL, the data of the “L”/“H” level stored in the non-inverted-side storage node SNt can be broken. As a second case, the data destruction at the time of the bit write mask operation of the write bit line WBLN as shown by FIG. 6A and FIG. 6B is exemplified. That is, by the data of the “H”/“L” level previously retained in the write bit line WBLN, the data of the “L”/“H” level stored in the inverted-side storage node SNb can be broken.

As a third case, when the latch cell LC allows the dual port operation, inter-port interference at the time of the reading operation is exemplified. That is, when the dual port operation is allowed, a write transfer gate and a read transfer gate can be made in the on state in the same period. In this case, at the time of the writing operation, the writing operation can be hindered depending on the data of the read bit line RBL. Similarly, at the time of the reading operation, the reading operation can be hindered depending on the data of the write bit line BLN.

As a specific example, a case in which the two storage nodes SNb/SNt store the “L” level/“H” level is assumed. Further, a case in which the read bit line RBL is previously retained at the “H” level is assumed. In this case, the inverted-side storage node SNb easily retains the “L” level. Such a state, when the inverted-side storage node SNb is rewritten form the “L” level to the “H” level, a rewriting operation may fail.

### Design Specifications of Latch Cell (Embodiment)

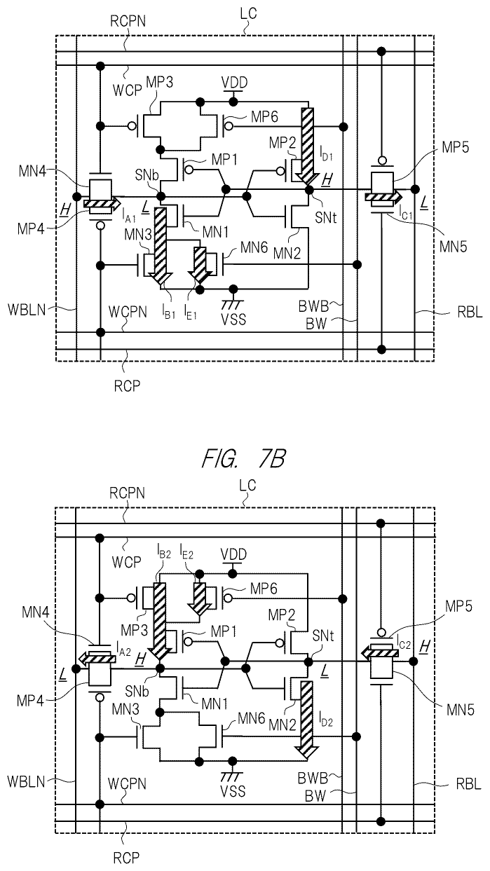

FIG. 7A is a schematic view showing one example of design specifications of the latch cell LC shown by FIG. 3. In FIG. 7A, an on-current value flowing in the pMOS transistor MP4 is set at “I_{A1}”. An on-current value flowing in the nMOS transistor MN1 and the nMOS transistor MN3 in series is set at “I_{B1}”. In addition, an on-current value flowing in the nMOS transistor MN5 is set at “I_{C1}”. An on-current value flowing in the pMOS transistor MP2 is set at “I_{D1}”. Further, an on-current value flowing in the nMOS transistor MN6 is set at “I_{E1}”.

Here, a case in which each of the inverted-side storage node SNb and the non-inverted-side storage node SNt stores the “L” level and the “H” level is assumed. A case in which the write bit line WBLN previously retains the “H” level is assumed. A case in which the read bit line BL previously retains the “L” level is assumed.

In this case, the stability of the latch cell LC decreases when “I_{A1}>I_{B1}”, when “I_{C1}>I_{D1}”, or when “I_{A1}>I_{E1}”. In such a case, for example, at the time of the reading operation or the bit write mask operation, the stability of the latch cell LC can be decreased. Note that at this time, the write transfer gate causes the pMOS transistor MP4 to be mainly operated in order to perform a charging operation to the inverted-side storage node SNb. In addition, the read transfer gate causes the nMOS transistor MN5 to mainly be operated in order to perform a discharging operation to the non-inverted-side storage node SNt.

Therefore, in the embodiment, as shown in FIG. 7A, the latch cell LC is configured so as to satisfy a relationship of “I_{A1}<I_{B1}”. In addition, the latch cell LC is configured so as to satisfy a relationship of “I_{C1}<I_{D1}”. Further, the latch cell LC is configured so as to satisfy a relationship of “I_{A1}<I_{E1}”. Consequently, the stability of the latch cell LC, that is, a retaining capacity of the data in the two storage nodes SNt, SNb is enhanced.

Specifically, for example, in FIG. 5A and FIG. 6A, a decrease amount of voltages capable of being generated in the non-inverted-side storage node SNt can be suppressed. Further, an increase amount of voltages capable of being generated in the inverted-side storage node SNb can be suppressed. Note that at the time of the writing operation, the driving operation by the write driver WDV is performed as described above. Therefore, even when the above-described relationships are satisfied, data can be correctly written, in other words, can be rewritten.

FIG. 7B is a schematic view showing one example of further design specifications of the latch cell LC shown by FIG. 3. In FIG. 7B, an on-current value flowing in the nMOS transistor MN4 is set to “I_{A2}”. An on-current value flowing in the pMOS transistor MP3 and the pMOS transistor MP5 in series is set to “I_{B2}”. In addition, an on-current value flowing in the pMOS transistor MP5 is set to “I_{C2}”. An on-current value flowing in the nMOS transistor MN2 is set to “I_{D2}”. Further, an on-current value flowing in the pMOS transistor MP6 is set to “I_{E2}”.

Here, a case in which each of the inverted-side storage node SNb and the non-inverted-side storage node SNt stores the “H” level and the “L” level is assumed. A case in which the write bit line WBLN previously retains the “L” level is assumed. A case in which the read bit line RBL previously retains the “H” level is assumed.

At this case, the stability of the latch cell LC decreases when “I_{A2}>I_{B2}”, when “I_{C2}>I_{D2}”, or when “I_{A2}>I_{E2}”. In this case, for example, at the time of the reading operation or the bit write mask operation, the stability of the latch cell LC can be decreased. Note that at this case, the write transfer gate causes the nMOS transistor MN4 to be mainly operated in order to perform the charging operation to the inverted-side storage node SNb. In addition, the read transfer gate causes the pMOS transistor MP5 to mainly be operated in order to perform the discharging operation to the non-inverted-side storage node SNt.

Therefore, in the embodiment, as shown in FIG. 7B, the latch cell LC is configured so as to satisfy a relationship of “I_{A2}<I_{B2}”. In addition, the latch cell LC is configured so as to satisfy a relationship of “I_{C2}<I_{D2}”. Further, the latch cell LC is configured so as to satisfy a relationship of “I_{A2}<I_{E2}”. Consequently, the stability of the latch cell LC, that is, the retaining capacity of the data in the two storage nodes SNt, SNb is enhanced.

Note that the on-current value of each nMOS transistor described above is determined by a drain current Id in a saturation region of the MOS transistor as shown by equation (1). In equation (1), the “μ” is mobility of electrons or holes. “Cₓ” is gate capacity per unit area. “V_{gs}” is a gate-source voltage. “Vₜₕ” is a threshold value. “W” is a gate width. “L” is a gate length.

$$Id = ( 1 / 2 ) \times μ \times {C}_{x} \times ( W / L ) \times {( {V}_{g s} - {V}_{t h} )}^{2} \qquad ( 1 )$$

### Main Effects by First Embodiment

As described above, in a method by the first embodiment, each latch cell configuring the D latch macro is configured by 10 or 12 MOS transistors. Consequently, in the semiconductor device having the small-capacity memory, the area saving can be achieved. Further, in the method by the first embodiment, the relationship between the on-current value of the MOS transistor configuring the transfer gate and the on-current value of the MOS transistor configuring the latch circuit is determined properly. Consequently, the stability of the latch cell is enhanced.

### Second Embodiment

### Design Specifications of Latch Cell

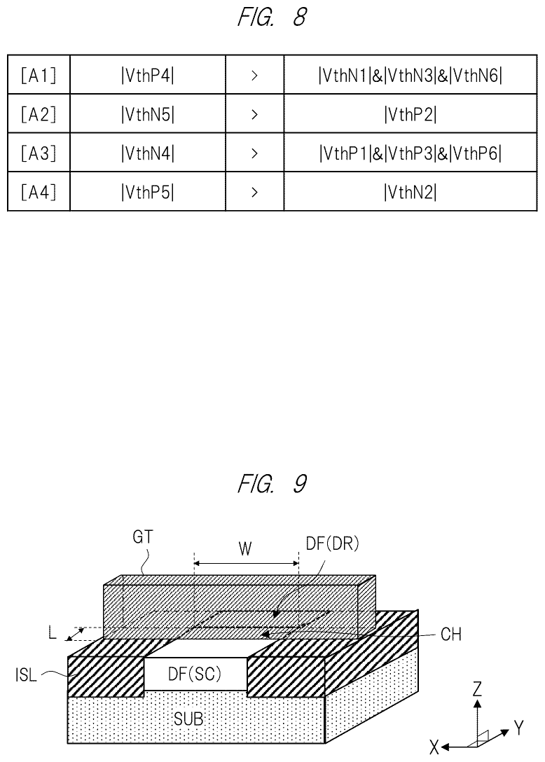

FIG. 8 is a view showing one example of the detailed design specification of the latch cell shown by FIG. 3, FIG. 7A, and FIG. 7B in a semiconductor device according to a second embodiment. FIG. 7A and FIG. 7B show design specifications of a current relation in the latch cell LC. In the second embodiment, this current relation is realized by setting a threshold value Vth based on equipment (1) described above. In FIG. 8, |VthP*| represents the threshold value set at the pMOS transistor MP* in FIG. 7A and FIG. 7B. Similarly, |VthN*| represents the threshold value set at the nMOS transistor MN* in FIG. 7A and FIG. 7B.

In FIG. 8, a magnitude relation of the threshold value Vth is defined by four conditions [A1], [A2], [A3], and [A4]. In condition [A1], the threshold value |VthP4| of the pMOS transistor MP4 becomes higher than the threshold values |VthN1|, |VthN3| of the 2 nMOS transistors MN1, MN3. Further, the threshold value |VthP4| of the pMOS transistor MP4 becomes higher than the threshold value |VthN6| of the nMOS transistor MN6.

In condition [A3], the threshold value |VthN4| of the pMOS transistor MP4 becomes higher than the 2 threshold values |VthP1|, |VthP3| of the 2 pMOS transistors MP1, MP3. Further, the threshold value |VthN4| of the nMOS transistor MN4 becomes higher than the threshold value |VthP6| of the pMOS transistors MP6.

In condition [A2], the threshold value |VthN5| of the nMOS transistor MN5 becomes higher than the threshold value |VthP2| of the pMOS transistors MP2. In condition [A4], the threshold value |VthP5| of the pMOS transistor MP5 becomes higher than the threshold value |VthN21 of the nMOS transistors MN2.

### Layout of Latch Cell

FIG. 9 is a perspective view showing a structure example of each MOS transistor configuring the latch cell in the semiconductor device according to the second embodiment. FIG. 9 shows a planar type MOS transistor. Here, a surface direction of a semiconductor substrate SUB is defined as an X-axis direction and a Y-axis direction, and a vertical direction to the surface direction is defined as a Z-axis direction. On the semiconductor substrate SUB, a diffusion layer DF extending in the Y-axis direction is formed. In the X-axis direction, insulation layers ISL are formed on both sides of the diffusion layer DF.

In addition, in the Z-axis direction, a gate layer GT is formed on the diffusion layer. The gate layer GT is made of, for example, a material representing polysilicon, and extends in the X-axis direction. A region of the diffusion layer DF intersecting with the gate layer GT becomes a channel region CH. On the channel region CH, the gate layer GT is formed via a not-shown gate insulation film. In addition, in the Y-axis direction, the diffusion layers located on both sides of the channel region CH is a source diffusion layer SC and a drain diffusion layer DR, respectively.

In the pMOS transistor, the source diffusion layer SC and the drain diffusion layer DR have p-type impurities. In addition, the channel region CH has n-type impurities. Meanwhile, in the nMOS transistor, the source diffusion layer SC and the drain diffusion layer DR have n-type impurities. In addition, the channel region CH has p-type impurities. Note that the gate length L is determined by a length in the Y-axis direction in the channel region CH and, eventually, a thickness of the gate layer GT. A gate width W is determined by a width in the X-axis direction of the channel region CH.

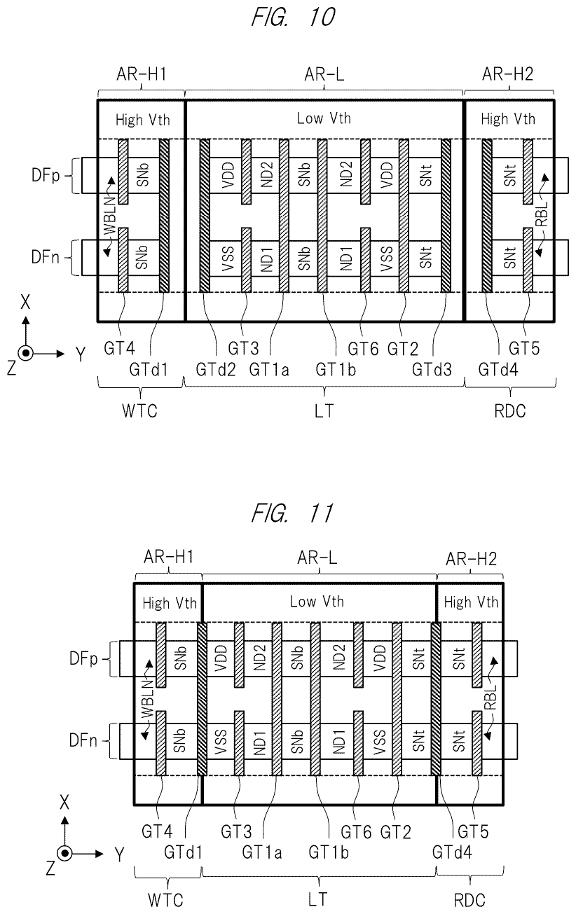

FIG. 10 is a schematic view showing a layout configuration example of the latch cell LC shown by FIG. 3 and FIG. 8. In FIG. 10, 1 transistor region AR-L and 2 transistor regions AR-H1, AR-H2 located on its both sides are provided in the Y-axis direction. The transistor region (first transistor region) AR-L is a region for realizing the relatively low threshold voltage Vth. Meanwhile, the 2 transistor regions (second transistor region and third transistor region) AR-H1, AR-H2 are regions for realizing the relatively high threshold voltage Vth.

In the transistor regions AR-L, AR-H1, AR-H2, 2 diffusion layers DFp, DFn extending in the Y-axis direction are formed alongside in the X-axis direction. The diffusion layer DFp is a diffusion layer for the pMOS transistor. The diffusion layer DFn is a diffusion layer for the nMOS transistor. Then, the transistor region AR-L for the low threshold voltage and the 2 transistor regions AR-H1, AR-H2 for the high threshold voltage are different from each other in, for example, an impurity concentration of the channel region CH.

Here, in the transistor region AR-L, 5 gate layers GT1a, GT1b, GT2, GT3, GT6 are provided. The 2 gate layers GT3, GT6 among them are in detail provided to the 2 diffusion layers DFp, DFn individually. Consequently, in the transistor region AR-L, the 4 pMOS transistors and the 4 nMOS transistors are formed. That is, in the transistor region AR-L, the latch circuit LC shown by FIG. 3 is formed.

Specifically, for example, by one of the 2 gate layers GT1a, GT1b, the pMOS transistor MP1 and the nMOS transistor MN1 are formed. Note that the other of the 2 gate layers GT1a, GT1b is a dummy gate layer capable of being generated due to a way to allocate the diffusion layer. In addition, by the gate layer GT2, the pMOS transistor MP6 and the nMOS transistor MN6 are formed. By the gate layer GT6, the pMOS transistor MP6 and the nMOS transistor MN6 are formed.

Meanwhile, in the transistor region AR=H1, 1 gate layer GT4 is provided. Specifically, the gate layer GT4 is provided to the 2 diffusion layers DFp, DFn individually. Consequently, in the transistor region AR-H1, the pMOS transistor MP4 and the nMOS transistor MN4 are formed. That is, in the transistor region AR-H1, the write port circuit WTC shown by FIG. 3 is formed.

In addition, in the transistor region AR-H2, the 1 gate layer GT5 is provided. Specifically, the gate layer GT5 is provided to the 2 diffusion regions DFp, DFn individually. Consequently, in the transistor region AR-H2, the pMOS transistor MP5 and the nMOS transistor MN5 are formed. That is, in the transistor region AR-H2, the read port circuit RDC shown by FIG. 3 is formed.

In this way, in FIG. 10, the latch circuit LC is arranged at a position between the write port circuit WTC and the read port circuit RDC in the Y-axis direction (first direction). Consequently, for example, the interference between the write bit lines WBLN connected to the write port circuit WTC and the read bit line RBL connected to the write port circuit RDC can be suppressed. In addition, for example, a layout space of each circuit configurating the data input/output circuit IOC shown by FIG. 2 becomes easier secured.

Note that in FIG. 10, 2 dummy gate layers GTd1, GTd2 for securing a separation space are provided at a border portion between the transistor region AR-L and the transistor region AR-H1. Similarly, 2 dummy gate layers GTd3, GTd4 for securing a separation space are provided at a border portion between the transistor region AR-L and the transistor region AR-H2.

To separate the regions different in the threshold voltage Vth depending on an applied manufacturing process, such a separation space may be required. That is, in FIG. 10, for example, the diffusion layer DFp in the transistor region AR-H1 is separated from the diffusion layer DFp in the adjacent transistor region AR-L. Note that the layout configuration example shown by FIG. 10 is not limited to the planar type MOS transistor as shown by FIG. 9, and is equally applicable also to FinFET described later.

FIG. 11 is a schematic view showing a layout configuration example different from that of FIG. 10 of the latch cell LC shown by FIG. 3 and FIG. 8. The latch cell LC shown by FIG. 11 is different from the case of FIG. 10 in the number of dummy gate layers. That is, in the border portion between the transistor region AT-L and the transistor region AF-H1, the 1 dummy gate layer GTd1 is provided. Similarly, also in the border portion between the transistor region AT-L and the transistor region AF-H2, the 1 dummy gate layer GTd4 is provided.

By sandwiching the 1 dummy gate layer like this depending on the applied manufacturing process, the regions different in the threshold voltage Vth may be separated. When the layout configuration example shown by FIG. 11 can be applied, an area of the latch cell LC can further be saved in comparison with the case of FIG. 10.

About Difference with Latch Cell (Comparative Example)

FIG. 19 is a schematic view showing a layout configuration example of the latch cell LCx shown by FIG. 18. In FIG. 19, the 2 transistor regions AR-H, AR-L are formed. The transistor region AR-H is a region for realizing the relatively high threshold voltage. The transistor region AR-L is a region for realizing the relatively low threshold voltage. Then, on the contrary to the case of FIG. 11, the latch circuit LC shown by FIG. 18 is formed in the transistor region AR-H. Meanwhile, the write port circuit WTC and the read port circuit RDC shown by FIG. 18 are formed in the transistor region AR-L.

Here, the latch cell LCx shown by FIG. 19 requires a total of 10 gate layers GT including the 1 dummy gate layer GTd. Meanwhile, the latch cell LC shown by FIG. 11 has only to have a total of 9 gate layers GT including the 2 dummy gate layers GTd1, GTd2. In this way, in FIG. 11, even when the 2 dummy gate layers are provided, the area of the latch cell LC can be saved in comparison with the case of FIG. 19.

### Main Effects by Second Embodiment

As described above, also by using the way by the second embodiment, the same effects as the various effects described in the first embodiment can be obtained. Further, in the way by the second embodiment, by properly setting the threshold voltage Vth, the stability of the latch cell is enhanced. The way by the second embodiment is particularly advantageous as the way to realize the area saving in a layout rule in which a degree of freedom about, for example, a line width, pitch, and the like is comparatively low.

### Third Embodiment

### Design Specifications of Latch Cell

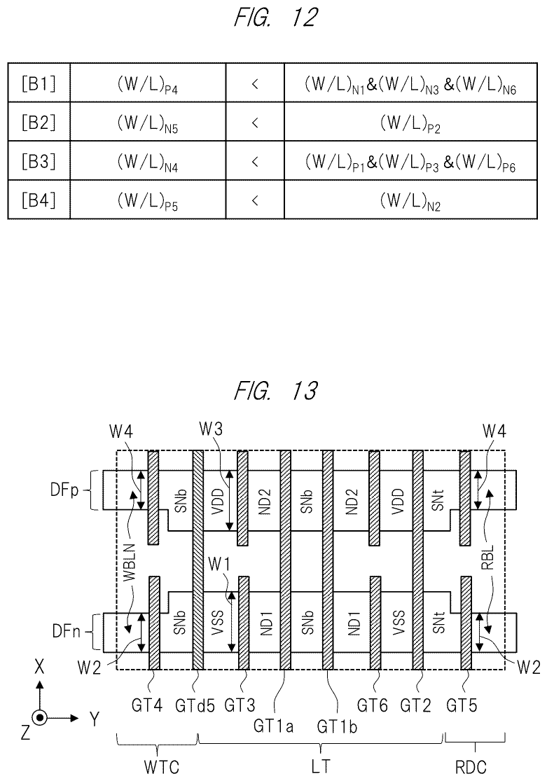

FIG. 12 is a view showing one example a detailed design specifications of the latch cell LC shown by FIG. 3, FIG. 7A, and FIG. 7B in a semiconductor device according to a third embodiment. In the second embodiment, the current relation shown by FIG. 7A and FIG. 7B has been realized by setting the threshold voltage Vth. In the third embodiment, this current relation is realized by setting “gate width W/gate length L” based on equipment (1) described above. (W/L)_{p*} in FIG. 12 represents (W/L) set by the pMOS transistor MP* shown by FIG. 7A and FIG. 7B. Similarly, (W/L)_{N*} represents (W/L) set by the nMOS transistor MN* shown by FIG. 7A and FIG. 7B.

In FIG. 12, by four conditions [B1], [B2], [B3], [B4], a magnitude of the (W/L) is determined. In condition [B1], (W/L) of the pMOS transistor MP4 becomes smaller than (W/L) of the 2 nMOS transistors MN1, MN3. Further, (W/L) of the pMOS transistor MP4 becomes smaller than (W/L) of the nMOS transistor MN6.

In condition [B3], (W/L) of the nMOS transistor MN4 becomes smaller than (W/L) of the 2 pMOS transistors MP1, MP3. Further, (W/L) of the nMOS transistor MN4 becomes smaller than (W/L) of the pMOS transistor MP6.

In condition [B2], (W/L) of the nMOS transistor MN5 becomes smaller than (W/L) of the pMOS transistor MP2. In condition [B4], (W/L) of the pMOS transistor MP5 becomes smaller than (W/L) of the nMOS transistor MN2.

### Layout of Latch Cell

FIG. 13 is a schematic view showing a layout configuration example of the latch cell LC shown by FIG. 3 and FIG. 12. In FIG. 13, each MOS transistor is arranged similarly to the case of FIG. 11. That is, in the Y-axis direction, the write port circuit WTC and the read port circuit RDC are arranged on both sides of the latch circuit LT, respectively. However, a case of FIG. 13 is different from the case of FIG. 11 in the following three points. As a first different point, the threshold voltages Vth of the respective nMOS transistors are same. The threshold voltages Vth of the respective pMOS transistors are also same.

As a second different point, here, not the 2 but the one dummy gate layer GTd5 is provided. The dummy gate layer GTd5 is provided between the pMOS transistor MP3 and nMOS transistor MN4 and the pMOS transistor MP3 and nMOS transistor MN3. The dummy gate layer GTd5 is different from the case of FIG. 11, and can be generated and obtained due to how to allocate the diffusion layer, but not for separating the transistor region.

Then, as a third different point, each of the 2 diffusion layers DFp, DFn has two types of sizes in the X-axis direction. Consequently, the 4 nMOS transistors MN1 to MN3, MN6 configurating the latch circuit LT have a same-size gate width (first gate width) W1. Meanwhile, the 2 nMOS transistors MN4, MN5 configurating the write port circuit WTC and the read port circuit RDC have a same-size gate width (second gate width) W2. Then, the gate width W2 becomes smaller than the gate width W1.

Similarly, the 4 pMOS transistors MP1 to MP3, MP6 configurating the latch circuit LT have a same-size gate width (third gate width) W3. Meanwhile, the 2 pMOS transistors MP4, MP5 configurating the write port circuit WTC and the read port circuit RDC have a same-size gate width (fourth gate width) W4. Then, the gate width W4 becomes smaller than the gate width W3.

Note that the gate widths L of each pMOS transistor and each nMOS transistor are same. Meanwhile, for example, the gate width W1 of the nMOS transistor and the gate width W3 of the pMOS transistor may be same depending on the manufacturing process. That is, for example, when a difference between the mobility of electrons and the mobility of holes that are shown by equation (1) can be omitted, the gate width W1 and the gate width W3 may be equal. In addition, the gate width W2 and the gate width W4 may also be equal.

Meanwhile, when the difference between the mobility of electrons and the mobility of holes cannot be omitted, for example, the gate width W3 of the pMOS transistor may be larger than the gate width W1 of the nMOS transistor. Even in this case, to realize the current relation shown by FIG. 12, the diffusion layer DFn is configurated so as to have two types of gate widths W1, W3. The diffusion layer DFp is also configurated so as to have two types of gate widths W3, W4.

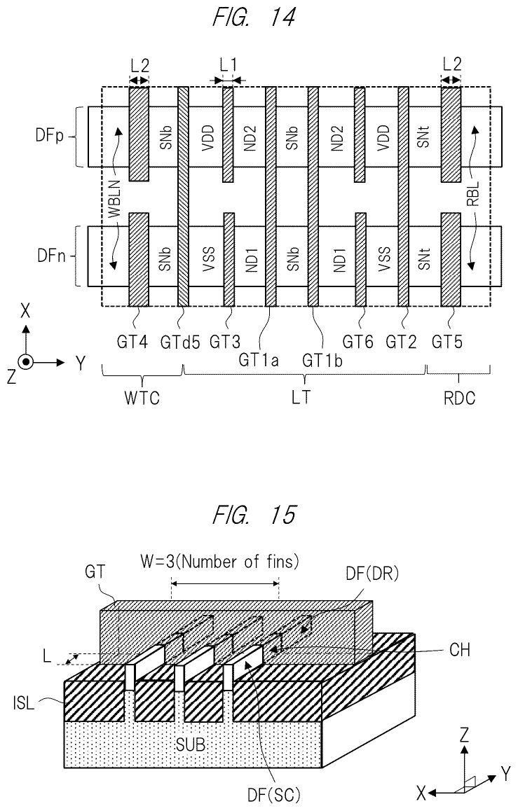

FIG. 14 is a schematic view showing a layout configuration example different from a case of FIG. 13 in the latch cell LC shown by FIG. 3 and FIG. 12. In FIG. 14, each MOS transistor is arranged similarly to the case of FIG. 13. That is, in the Y-axis direction, the write port circuit WTC and the read port circuit RDC are arranged on the both sides of the latch circuit LC, respectively. However, a case of FIG. 14 is different from the case of FIG. 13 in the following 2 points. As a first different point, each pMOS transistor has the same-size gate width W. Each nMOS transistor also has the same-size gate width W.

As a second different point, the gate layer GT has two types of sizes in the Y-axis direction. Consequently, the 4 nMOS transistors MN1 to MN3, MN6 configurating the latch circuit LC have a same-size gate length (first gate length) L1. The 4 pMOS transistors MP1 to MP3, MP6 configurating the latch circuit LC have the above-described gate length L1. Meanwhile, the 2 nMOS transistors MN4, MN5 configurating the write port circuit WTC and the read port circuit RDC have a same-size gate length (second gate length) L2. The 2 pMOS transistors MP4, MP5 configurating the latch circuit LC also have the above-described gate length L2. Then, the gate length L2 becomes larger than the gate length L1.

### Main Effects by Third Embodiment

As described above, also by using the method by the third embodiment, the same effects as those described in the first embodiment are obtained. Further, in the method by the third embodiment, by properly setting the “gate length W/gate length L”, the stability of the latch cell LC is enhanced. For example, when the second embodiment is different to apply, that is, when the manufacturing process in which the plurality of threshold voltages Vth is difficult to set is used, the method by the third embodiment may be used. In addition, for example, each method shown by FIG. 13 and FIG. 14 can be appropriately selected according to the applied manufacturing process. Further, each method described above can be appropriately obtained according to required performance to the latch cell LC, for example, according to target values of an area, a speed, a leak current, and the like.

### Fourth Embodiment

### Layout of Latch Cell

FIG. 15 is a perspective view showing a configuration example of each MOS transistor configurating a latch cell in a semiconductor device according a fourth embodiment. FIG. 15 shows a FinFET, which is different from the planar type MOS transistor shown by FIG. 9. In the FinFET, the diffusion layer DF is formed by a plurality of Fins, in this example, 3 Fins. The plurality of Fins are formed alongside in the X-axis direction, and extend in the Y-axis direction. The gate layer GT is formed so as to cover 3 faces among 4 faces, which form a surface of each Fin, via a not-shown gate insulation film.

A region of the diffusion layer DF covered by this gate layer GT is the channel region CH. In addition, in the Y-axis direction, the diffusion layers DF located on both sides of the channel region CH are a source diffusion layer SC and a drain diffusion layer DR, respectively. By using such a FinFET, a contact area between the gate layer GT and the channel region CH is increased. Therefore, for example, the performance of the transistor can be improved in addition to the reduction of the leak current. In addition, in the FinFET, the gate width W is determined by the number of Fins.

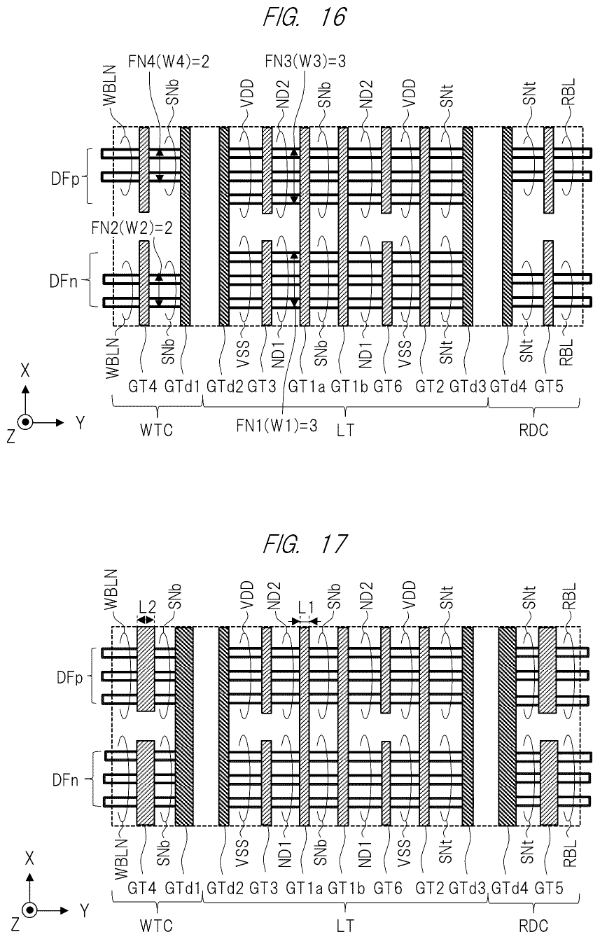

FIG. 16 is a schematic view showing a layout configuration example of the latch cell LC shown by FIG. 3 and FIG. 12 in the semiconductor device according to the fourth embodiment. Also in the fourth embodiment similarly to the case of the third embodiment, the current relation shown by FIG. 3 is realized by setting the “gate width W/gate length L”. However, the fourth embodiment is different from the case of the third embodiment, and each MOS transistor is configurated by the FinFET shown by FIG. 15.

In FIG. 16, each MOS transistor is arranged similarly to the case of FIG. 13. That is, in the Y-axis direction, the write port circuit WTC and the read port circuit RDC are arranged on both sides of the latch cell LC, respectively. In addition, each of the 2 diffusion layers DFp, DFn has 2 types of sizes and, eventually, the gate length W in the X-axis direction. However, FIG. 16 is different from the case of FIG. 13 in the following 2 points.

As a first different point, a relation of the gate length W shown by FIG. 13 is realized by the number of Fins. That is, the 4 nMOS transistors MN1 to MN3, MN6 have the same number of Fins, here, 3 Fins (first Fin number) FN1. The remaining 2 nMOS transistors MN4, MN5 also have the same number of Fins, here, 2 Fins (second Fin number) FN2. Then, the Fin number F2 becomes smaller than the Fin number F1.

Similarly, the 4 pMOS transistors MP1 to MP3, MP6 have the same number of Fins, here, 3 Fins (third Fin number) FN3. The remaining 2 pMOS transistors MP4, MP5 also have the same number of Fins, here, 2 Fins (fourth Fin number) FN4. Then, the Fin number F4 becomes smaller than the Fin number F3. Note that all of the gate lengths L of the respective MOS transistors may be the same size.

Here, similarly to the case of FIG. 13, depending on the manufacturing process, the number of Fins FN1 and the number of Fins FN2 may be the same. In addition, the number of Fins FN3 and the number of Fins FN4 may be the same. Particularly, when the FinFET is used, the difference between the mobility of electrons and the mobility of holes can be ignored in comparison with the case of using the planar type transistor.

As a second different point, the dummy gage layer for switching the number of Fins is formed. That is, the 2 dummy gate layers GTd1, GTd2 are formed between the write port circuit WTC and the latch circuit LC. Similarly, the 2 dummy gate layers GTd3, GTd4 are formed between the read port circuit RDC and the latch circuit LC.

FIG. 17 is a schematic view showing a layout configuration example different from a case of FIG. 16 of the latch cell LC shown by FIG. 3 and FIG. 12. In FIG. 17, almost the same layout as that in the case of FIG. 16 is shown. However, FIG. 17 is different from the case of FIG. 16 in the following 3 points. As a first different point, the number of Fins and, eventually, the gate width W that each MOS transistor is the same number, here, 3.

As a second different point, the 2 types of sizes are provided to the gate length L of each MOS transistor similarly to the case of FIG. 14. That is, the 4 nMOS transistors MN1 to MN 3, MN6 and the 4 pMOS transistors MP1 to MP3, MP6 have the same-size gate length L1. The remaining 2 nMOS transistors MN4, MN5 and the remaining 2 pMOS transistors MP4, MP5 also have the same-size gate length L2. Then, the gate length L2 becomes larger than the gate length L1.

As a third different point, on a write port circuit WTC side, the dummy gate layer GTd1 is formed with the gate length L2, while the dummy gate layer GTd2 is formed with the gate length L1. Similarly, on a read port circuit RDC side, the dummy gate layer GTd4 is formed with the gate length L2, while the dummy gate layer GTd3 is formed with the gate length L1.

### Main Effects by Fourth Embodiment

As described above, also by using the method by the fourth embodiment, the same effects as the various effects described in the first embodiment and the third embodiment are obtained. Further, in the method by the fourth embodiment, for example, the stability of the latch cell LC is enhanced by properly setting the number of Fins. In addition, by using the FinFET, the performance of each MOS transistor can be improved and, for example, power consumption of the semiconductor device can be reduced.

As described above, the invention made by the inventors of the present application has been specifically explained based on the embodiments, but the present invention is not limited to the above embodiments and can be variously modified within a range not departing from the gist thereof. For example, the above embodiments have been detailed for clearly explaining the present invention, and are not limited to an embodiment having not necessarily all configurations explained. Also, a part of the configuration of one embodiment may be replaced with the configuration of another embodiment, and the configuration of one embodiment may be added to the configuration of another embodiment. Furthermore, another configuration may be added to a part of the configuration of each embodiment, and a part of the configuration of each embodiment may be eliminated or replaced with another configuration.

What is claimed is:

1. A semiconductor device comprising:
a non-inverted-side write selection line and an inverted-side write selection line that are activated at a time of a writing operation;
a non-inverted-side read selection line and an inverted-side read selection line that are activated at a time of a reading operation;
a plurality of latch cells connected to the non-inverted-side write selection line and the inverted-side write selection line and to non-inverted-side read selection line and the inverted-side read selection line;
a plurality of read bit lines transferring read date from the plurality of latch cells; and
a plurality of write bit lines transferring write date from the plurality of latch cells,
wherein each of the plurality of latch cells has:
a first storage node and a second storage node that store complementary date;
a first nMOS transistor connected between the first storage node and an intermedia node, a gate of the first nMOS transistor being connected to the second storage node;
a second nMOS transistor connected between the second storage node and a low-potential-side power supply voltage node, a gate of the second nMOS transistor being connected to the first storage node;
a third nMOS transistor connected between the first intermediate node and the low-potential-side power supply voltage node, a gate of the third nMOS transistor being connected to the inverted-side write selection line;
a fourth nMOS transistor connected between any of the plurality of write bit lines and the first storage node, a gate of the fourth nMOS transistor being connected to the non-inverted-side write selection line;
a fifth nMOS transistor connected between any of the plurality of read bit lines and the second storage node, a gate of the fifth nMOS transistor being connected to the non-inverted-side read selection line;
a first pMOS transistor connected between the first storage node and the second intermediate node, a gate of the first pMOS transistor being connected to the second storge node;
a second pMOS transistor connected between the second storage node and a high-potential-side power supply voltage node, a gate of the second pMOS transistor being connected to the first storge node;
a third pMOS transistor connected between the second intermediate node and the high-potential-side power supply voltage node, a gate of the third pMOS transistor being connected to the non-inverted-side write selection line;
a fourth pMOS transistor connected between any of the plurality of write bit lines and the first storge node, a gate of the fourth pMOS transistor being connected to the inverted-side read selection line; and
a fifth pMOS transistor connected between any of the plurality of read bit lines and the second storge node, a gate of the fifth pMOS transistor being connected to the inverted-side read selection line.

2. The semiconductor device according to claim 1,
wherein when an on-current value flowing in the fourth pMOS transistor is “1_{A1}” and an on-current value flowing in the first nMOS transistor and the third nMOS transistor is “1_{B1}”, the semiconductor device is configured so as to satisfy a relation of “1_{A1}<1_{B1}”,
wherein when an on-current value flowing in the fifth nMOS transistor is “1_{C1}” and an on-current value flowing in the second pMOS transistor is “1_{D1}”, the semiconductor device is configured so as to satisfy a relation of “1_{C1}<1_{D1}”,
wherein when an on-current value flowing in the fourth nMOS transistor is “1_{A2}” and an on-current value flowing in the third pMOS transistor and the first pMOS transistor is “1_{B2}”, the semiconductor device is configured so as to satisfy a relation of “1_{A2}<1_{B2}”, and
wherein when an on-current value flowing in the fifth pMOS transistor is “1_{C2}” and an on-current value flowing in the second nMOS transistor is “1_{D2}”, the semiconductor device is configured so as to satisfy a relation of “1_{C2}<1_{D2}”.

3. The semiconductor device according to claim 2,
wherein a threshold voltage of the fourth pMOS transistor is higher than threshold voltages of the first nMOS transistor and the third nMOS transistor,
wherein a threshold voltage of the fifth nMOS transistor is higher than a threshold voltage of the second pMOS,
wherein a threshold voltage of the fourth nMOS transistor is higher than threshold voltages of the first pMOS transistor and the third pMOS transistor, and
wherein a threshold voltage of the fifth pMOS transistor is higher than a threshold voltage of the second nMOS transistor.

4. The semiconductor device according to claim 3, further comprising:
a first transistor region that is a region for realizing a relatively low threshold voltage; and
a second transistor and a third transistor that are regions for realizing a relatively high threshold voltage and that are arranged on both sides of the first transistor region in a first direction,
wherein the first nMOS transistor, the second nMOS transistor, the third nMOS transistor, the first pMOS transistor, the second pMOS transistor, and the third pMOS transistor are formed in the second transistor region,
wherein the fourth nMOS transistor and the fourth pMOS transistor are formed in the second transistor region, and
wherein the fifth nMOS transistor and the fifth pMOS transistor are formed in the third transistor region.

5. The semiconductor device according to claim 2,
wherein “gate width/gate length” of the fourth pMOS transistor is smaller than “gate width/gate length” of the first nMOS transistor and “gate width/gate length” of the third nMOS transistor,
wherein “gate width/gate length” of the fifth nMOS transistor is smaller than “gate width/gate length” of the second pMOS transistor,
wherein “gate width/gate length” of the fourth nMOS transistor is smaller than “gate width/gate length” of the first pMOS transistor and “gate width/gate length” of the third pMOS transistor, and
wherein “gate width/gate length” of the fifth pMOS transistor is smaller than “gate width/gate length” of the second nMOS transistor.

6. The semiconductor device according to claim 2,
wherein the first nMOS transistor, the second nMOS transistor, and the third nMOS transistor are arranged between the fourth nMOS transistor and the fifth nMOS transistor in a first direction, and
wherein the first pMOS transistor, the second pMOS transistor, and the third pMOS transistor are arranged between the fourth pMOS transistor and the fifth pMOS transistor in the first direction.

7. The semiconductor device according to claim 6,
wherein the MOS transistors have the same length,
wherein the first nMOS transistor, the second nMOS transistor, and the third nMOS transistor have a same-size first gate width,
wherein the fourth nMOS transistor and the fifth nMOS transistor have a same-size second gate width,
wherein the second gate width is smaller than the first gate width,
wherein the first pMOS transistor, the second pMOS transistor, and the third pMOS transistor have a same-size third gate width,
wherein the fourth pMOS transistor and the fifth pMOS transistor have a same-size fourth gate width, and
wherein the fourth gate width is smaller than the third gate width.

8. The semiconductor device according to claim 6,
wherein the respective pMOS transistors have the same-size gate width,
wherein the respective nMOS transistors have the same-size gate width,
wherein the first nMOS transistor, the second nMOS transistor, and the third nMOS transistor, the first pMOS transistor, the second pMOS transistor, and the third pMOS transistor have the same-size first gate length,
wherein the nMOS transistor, the fifth nMOS transistor, the fourth pMOS transistor, and the fifth pMOS transistor have the same-size second gate length, and
wherein the second gate length is larger than the first gate length.

9. The semiconductor device according to claim 6,
wherein each MOS transistor is configured by FinFET,
wherein the first nMOS transistor, the second nMOS transistor, and the third nMOS transistor have a same first Fin number,
wherein the fourth nMOS transistor and the fifth nMOS transistor have a same second Fin number,
wherein the second Fin number is smaller than the first Fin number,
wherein the first pMOS transistor, the second pMOS transistor, and the third pMOS transistor have a same third Fin number,
wherein the fourth pMOS transistor and the fifth pMOS transistor have a same fourth Fin number, and
wherein the fourth Fin number is smaller than the third Fin number.

10. The semiconductor device according to claim 9,
wherein the first Fin number is a same as the third Fin number, and
wherein the second Fin number is a same as the fourth Fin number.

11. The semiconductor device according to claim 1, further comprising a plurality of non-inverted-side bit write mask selection lines and a plurality of inverted-side bit write mask selection lines that are activated in performing a writing operation of high impedance to any the plurality of latch cells,
wherein each of the plurality of latch cells further includes:
a sixth nMOS transistor connected between the first intermediate node and the low-potential-side power supply voltage node, a gate of the sixth nMOS transistor being connected to any of the plurality of non-inverted-side bit write mask selection lines; and
a sixth pMOS transistor connected between the second intermediate node and the high-potential-side power supply voltage node, a gate of the sixth pMOS transistor being connected to any of the plurality of inverted-side bit write mask selection lines.

12. The semiconductor device according to claim 11,
wherein when an on-current value flowing in the fourth pMOS transistor is “1_{A1}” and an on-current value flowing in the first nMOS transistor and the third nMOS transistor is “1_{B1}”, the semiconductor device is configured so as to satisfy a relation of “1_{A1}<1_{B1}”,
wherein when an on-current value flowing in the fifth nMOS transistor is “1_{C1}” and an on-current value flowing in the second pMOS transistor is “1_{D1}”, the semiconductor device is configured so as to satisfy a relation of “1_{C1}<1_{D1}”,
wherein when an on-current value flowing in the fourth nMOS transistor is “1_{A2}” and an on-current value flowing in the third pMOS transistor and the first pMOS transistor is “1_{B2}”, the semiconductor device is configured so as to satisfy a relation of “1_{A2}<1_{B2}”,
wherein when an on-current value flowing in the fifth pMOS transistor is “1_{C2}” and an on-current value flowing in the second nMOS transistor is “1_{D2}”, the semiconductor device is configured so as to satisfy a relation of “1_{C2}<1_{D2}”,
wherein when an on-current value flowing in the sixth nMOS transistor is “1_{E1}”, the semiconductor device is configured so as to satisfy a relation of “_{A1}<1_{E1}”, and
wherein when an on-current value flowing in the sixth fourth nMOS transistor is “1_{E2}”, the semiconductor device is configured so as to satisfy a relation of “1_{A2}<1_{E2}”.

13. The semiconductor device according to claim 1, further comprising:
a read latch circuit inputting and latching the read date transferred to the plurality of read bit lines without passing through a sense amplifier.
